(19) United States
(12) Patent Application Publication
(10) Pub. No.: US 2025/0384945 A1
(43) Pub. Date: Dec. 18, 2025

(54) PROBABILISTIC DISTURBANCE ERROR HANDLING FOR A MEMORY SYSTEM

(71) Applicant: Micron Technology, Inc., Boise, ID (US)

(72) Inventors: Saurav Pundir, Bangalore (IN); Sridhar Prudviraj Gunda, Bangalore (IN); Guang Hu, Mountain View, CA (US)

(21) Appl. No.: 19/224,431

(22) Filed: May 30, 2025

Related U.S. Application Data
(60) Provisional application No. 63/659,545, filed on Jun. 13, 2024.

(51) Int. Cl. G11C 29/44

(52) U.S. Cl. CPC G11C 29/44

(57) ABSTRACT

Methods, systems, and devices for disturbance error handling for a memory system are described. For example, a memory system may determine that a first scan on a block of memory cells identified an error condition that satisfies a threshold (e.g., due to a relatively high bit error rate for a first portion of the block), and that one or more other scans on the block did not identify another error condition that satisfies another threshold (e.g., due to a relatively low bit error rate elsewhere in the block). Under such conditions (e.g., for an intermediate level of disturbance), the memory system may relocate less than all of the data stored at the block. In some examples, the portion of the data that is relocated may correspond to a word line associated with an identified error and one or more word lines adjacent to the word line.

### CROSS REFERENCE

The present Application for Patent claims priority to U.S. Patent Application No. 63/659,545 by Pundir et al., entitled “PROBABILISTIC DISTURBANCE ERROR HANDLING FOR A MEMORY SYSTEM,” filed Jun. 13, 2024, which is assigned to the assignee hereof, and which is expressly incorporated by reference in its entirety herein.

### TECHNICAL FIELD

The following relates to one or more systems for memory, including disturbance error handling for a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports disturbance error handling for a memory system in accordance with examples as disclosed herein.

FIG. 2 shows an example of a block architecture that supports disturbance error handling for a memory system in accordance with examples as disclosed herein.

FIG. 3 shows an example of a flowchart that supports disturbance error handling for a memory system in accordance with examples as disclosed herein.

FIG. 4 shows a block diagram of a memory system that supports disturbance error handling for a memory system in accordance with examples as disclosed herein.

FIG. 5 shows a flowchart illustrating a method or methods that support disturbance error handling for a memory system in accordance with examples as disclosed herein.

### DETAILED DESCRIPTION

In some memory systems, successive (e.g., repeated) access operations performed on a word line of a memory device may cause errors (e.g., disturbance errors, read disturb errors) at memory cells along the word line or along one or more adjacent word lines. Some memory systems may implement error handling techniques (e.g., error-preventative techniques, read scrub operations) to scan blocks of memory cells for errors. In some examples, such error handling may involve performing a set of error scans on a block of memory cells and relocating all of the data stored at the block if at least one of the scans indicates an error (e.g., if a bit error rate associated with a scan is above or otherwise satisfies a threshold value). However, relocating all of the data of the scanned block may be time-consuming, may be associated with relatively high power consumption, or may be associated with adverse write amplification, including for relatively large block sizes.

In accordance with examples as disclosed herein, disturbance error handling may be configured for relocating data from a full block or a portion of a block (e.g., fewer than all of the memory cells of the block, less than all of the data of the block) under certain conditions. For example, a memory system may determine that a first scan of a set of scans on a block identified an error condition that satisfies a threshold (e.g., due to a relatively high bit error rate for a first portion of the block). However, the memory system may also determine that one or more other scans of the set of scans on the block did not identify another error condition that satisfies another threshold (e.g., due to a relatively low bit error rate elsewhere in the block), which may indicate an intermediate level of disturbance of the block. Under such conditions (e.g., for an intermediate level of disturbance), the memory system may relocate less than all of the data stored at the block. In some examples, the portion of the data that is relocated may correspond to a target word line (e.g., associated with an identified error) and, in some examples, one or more word lines adjacent to the target word line. The target word line may correspond to a word line that was probabilistically likely to contain errors (e.g., based on prior access operations) and, in some cases, may be adjacent to a word line that was repeatedly accessed. In some examples, after relocating the portion of the data stored at the block, an indication of the block may be added to a priority list for error scans (e.g., media scans, background scans, periodic scans), which may support scanning the block for errors at a later time and relocating all of the data stored at the block if further errors are detected. Accordingly, disturbance error handling in accordance with the described techniques may support relocating less than all of the data of a block identified as having an intermediate level of errors, thereby reducing latency, power consumption, and write amplification associated with handling disturbance errors.

In addition to applicability in memory systems as described herein, techniques for disturbance error handling may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing the duration to perform disturbance handling operations, which may reduce memory system latency, improve memory system responsiveness, or otherwise improve user experience.

Features of the disclosure are illustrated and described in the context of systems, devices, and circuits. Features of the disclosure are further illustrated and described in the context of block architectures and flowcharts.

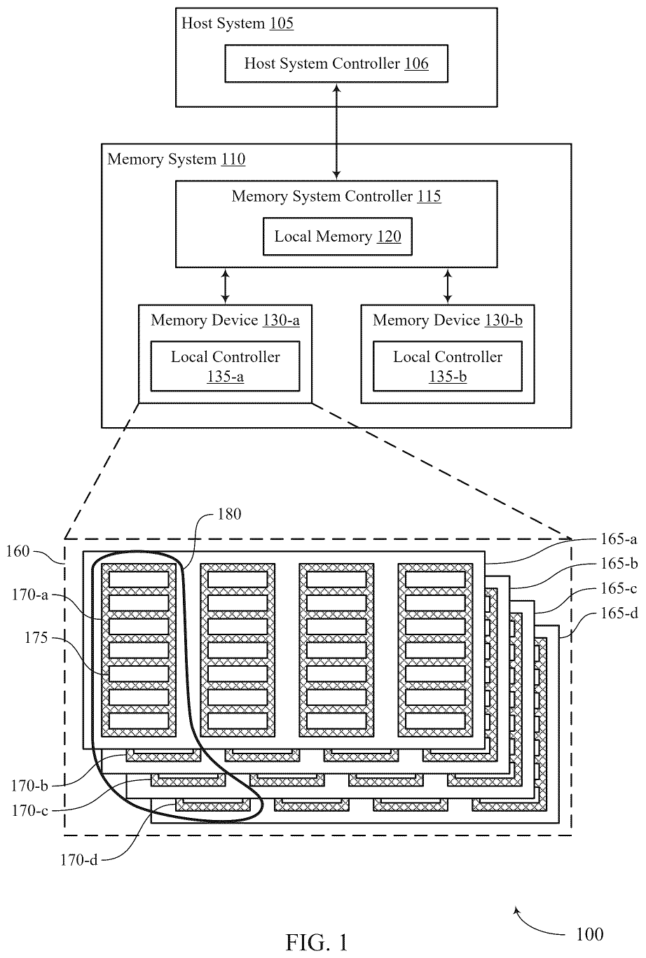

FIG. 1 shows an example of a system 100 that supports disturbance error handling for a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations-which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some memory systems 110, successive (e.g., repeated) access operations performed on a word line of a memory device 130 may cause errors (e.g., disturbance errors, read disturb errors) at memory cells along the word line or along one or more adjacent word lines. Some memory systems 110 may implement error handling techniques (e.g., read scrub operations, by a memory system controller 115, one or more local controllers 135, or a combination thereof) to scan blocks of memory cells (e.g., blocks 170, planes 165, virtual blocks 180) for errors. In some examples, such error handling may involve performing a set of error scans on a block of memory cells and relocating all of the data stored at the block (e.g., to a different block) if at least one of the scans indicates an error (e.g., if a bit error rate associated with a scan is above or otherwise satisfies a threshold value). However, relocating all of the data of the scanned block of memory cells may be time-consuming, may be associated with relatively high power consumption, or may be associated with adverse write amplification, including for relatively large block sizes.

In accordance with examples as disclosed herein, a memory system 110 (e.g., a memory system controller 115, one or more local controllers 135, or a combination thereof) may be configured to support techniques for disturbance error handling (e.g., probabilistic disturbance error handling), which may include relocating data from a portion of a block of memory cells (e.g., fewer than all of the memory cells of the block, less than all of the data of the block) under certain conditions. For example, a memory system 110 may determine that a first scan of a set of scans on a block of memory cells (e.g., a block 170, a plane 165, a virtual block 180, a group of pages 175) identified an error condition that satisfies a threshold (e.g., due to a relatively high bit error rate for a first portion of the block). However, the memory system 110 may also determine that one or more other scans of the set of scans on the block did not identify another error condition that satisfies another threshold (e.g., due to a relatively low bit error rate elsewhere in the block), which may indicate an intermediate level of disturbance of the block. Under such conditions (e.g., for an intermediate level of disturbance), the memory system 110 may relocate less than all of the data stored at the block. In some examples, after relocating the portion of the data stored at the block, an indication of the block may be added to a priority list for error scans (e.g., media scans, background scans, periodic scans), which may support scanning the block for errors at a later time and relocating all of the data stored at the block if further errors are detected. Accordingly, disturbance error handling in accordance with the described techniques may support relocating less than all of the data of a block identified as having an intermediate level of errors, thereby reducing latency, power consumption, and write amplification associated with handling disturbance errors.

The system 100 may include any quantity of non-transitory computer readable media that support disturbance error handling for a memory system 110. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

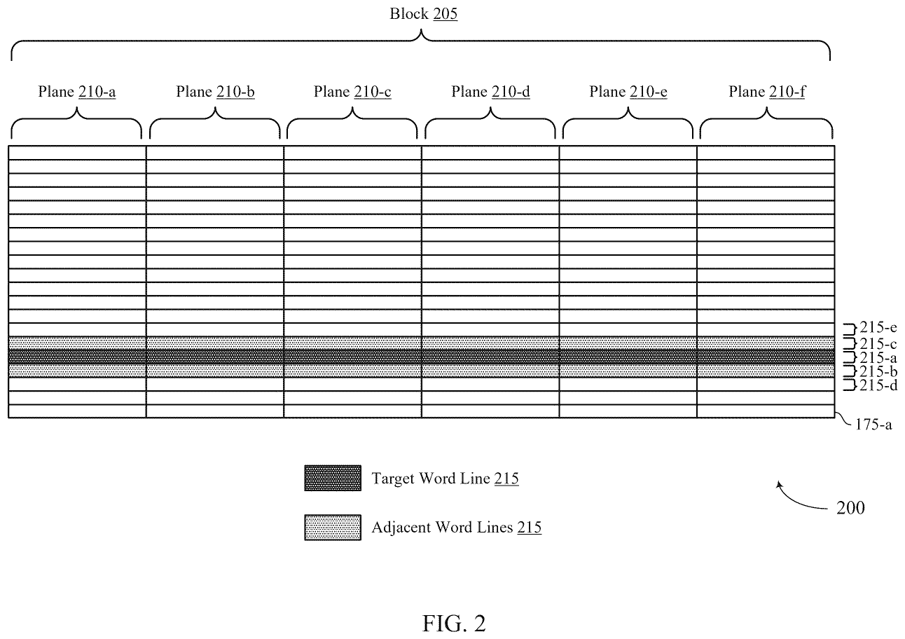

FIG. 2 shows an example of a block architecture 200 that supports disturbance error handling for a memory system in accordance with examples as disclosed herein. The block architecture 200 illustrates an example of a block 205 (e.g., a block of memory cells, a block of a memory device 130, a block of a memory system 110), which may include a set of multiple pages 175-a. In the example of block architecture 200, the block 205 includes a set of multiple planes 210 (e.g., planes 210-a, 210-b, 210-c, 210-d, 210-c, and 210-f), each of which may be an example of a plane 165. Thus, in some examples, a block 205 may be an example of a virtual block 180. However, a block 205 in accordance with the described techniques may include any quantity of one or more planes 210, or may not be associated with planes 210. Further, in the example of block architecture 200, the block 205 illustrates an implementation of a set of multiple word lines 215 (e.g., word lines 215-a through 215-c, among other word lines 215), and each of the pages 175-a may be associated with (e.g., activated by, coupled with) one of the word lines 215. A block 205 may include 278 word lines 215, among other quantities of multiple word lines. The block architecture 200 illustrates an example in which word lines 215 span multiple planes 210 (e.g., each of the planes 210 of the block 205, activating a respective page 175-a in multiple planes 210), but word lines 215 in accordance with the described techniques may span fewer than all of the planes 210 of a block 205, or may be configured in another manner.

In some cases, memory cells of a block 205 may experience disturbances along one or more word lines 215. For example, repeated access operations on a same word line 215 or on one or more nearby (e.g., physically adjacent, physically nearby, neighboring) word lines 215 may cause memory cells along at least one word line 215 to experience a disturbance to a stored logic state (e.g., a read disturbance, a write disturbance, a voltage disturbance, a charge disturbance, a charge loss disturbance), which may cause one or more memory cells to lose a written logic state, thereby leading to errors (e.g., read errors, disturbance errors).

In some examples, a memory system 110 may be configured to perform one or more aspects of disturbance error handling (e.g., probabilistic disturbance error handling or other techniques) as described herein. For example, a memory system 110 (e.g., a memory system controller 115, one or more local controllers 135, or a combination thereof) may be configured to select a target word line 215 (e.g., word line 215-a) that may be associated with read errors probabilistically (e.g., based on previous access operations, such as repeated access to one or more word lines adjacent to the target word line 215).

Disturbance error handling (e.g., probabilistic disturbance error handling) may be based on a set of scans, which may be referred to as a set of read bit error rate (RBER) scans. A first scan (e.g., a first RBER scan, an RBER1 scan, a hot scan) may correspond to a scan of a target word line 215 (e.g., word line 215-a). In various examples, a first scan may refer to scanning a target word line 215 for errors in one plane 210 (e.g., a selected plane 210, a plane 210 corresponding to a read operation, a page 175-a of a plane 210 associated with the target word line 215), or a set of multiple planes 210 (e.g., all planes 210) of the block 205. A second scan (e.g., a second RBER scan, an RBER2 scan, a cold scan) may correspond to a scan of one or more word lines 215 adjacent to a target word line 215 (e.g., one or more physically adjacent word lines 215, one or more immediately adjacent word lines 215-b and 215-c). In some examples, a second scan may include scans of one or more word lines 215 that are beyond those immediately adjacent to a target word line 215 (e.g., word lines 215-d and 215-c, for a second scan that scans word lines 215-b through 215-c). In various examples, a second scan may refer to scanning adjacent word lines 215 for errors in one plane 210 or a set of multiple planes 210 (e.g., all planes 210) of the block 205, which, in some examples, may be selected to be different than planes 210 selected for a first scan. In some examples, the quantity of adjacent word lines 215 to be scanned for a second scan may be configurable (e.g., at the memory system 110, by a host system 105, by a manufacturing configuration). A third scan (e.g., a third RBER scan, an RBER3 scan) may correspond to a scan of one or more word lines 215 that are configured for scanning independently from a target word line 215 (e.g., preconfigured, configured based on access history, at a memory system controller 115, via a configuration set mConfig). For example, one or more word lines 215 configured for a third scan may include one or more weak word lines 215 (e.g., word lines 215 determined to have a high probability of exhibiting high bit error rates, heavily-disturbed word lines 215). In various implementations, disturbance error handling may be based on a first scan and one or more second scans, on a first scan and one or more third scans, or on a first scan with one or more second scans and one or more third scans, in accordance with the described techniques. Although some aspects are described with reference to RBER scans, the described techniques for disturbance error handling may be based on any quantity of one or more of these and other error scans, which may evaluate various types of errors (e.g., bit errors, logic state errors, error locations in a block 205, error distributions of a block 205) observed during operation of a memory system 110. Such scans may include various evaluations of a presence or distribution of errors observed during various types of workloads, including read or write operations commanded by a host system 105, read or write operations based on an internal algorithm of a memory system 110 (e.g., initiated by a memory system controller 115, one or more local controllers 135, or a combination thereof, such as access operations of media management operations), or other workloads or combinations thereof that may be configured in a system 100

Each scan may be associated with (e.g., determine, indicate) a respective bit error rate, and each scan may be considered as a failure if the respective bit error rate satisfies (e.g., exceeds) a respective threshold. In some cases, the bit error rate may correspond to a quantity of errors detected by the scan (e.g., per page 175-a, per word line 215, per bit, per scan), and the errors may correspond to correctable errors, uncorrectable errors, or both. In some implementations, a memory system 110 may trigger relocation of all data (e.g., all valid data, all data intended to be maintained, all data including valid and invalid data) stored at the block 205 if any scan of the set of scans fails. However, relocating all data (e.g., valid data) stored at the block 205 may, in some circumstances, be unnecessarily time and power consuming. Relocating data of the entire block 205 may also be associated with a large quantity of write operations at the memory system 110, which, in some circumstances, may lead to unnecessary write amplification.

In accordance with examples as described herein, a memory system 110 may be configured to relocate a subset of the data stored at a block 205 based on (e.g., in response to, in accordance with) results of a set of scans on the block 205 For example, if a first scan corresponding to a target word line 215 and one or more adjacent word lines 215 (e.g., pages 175-a corresponding to the word line(s) 215, of one or more planes 210) indicates an error condition that satisfies a threshold (e.g., e.g., due to a relatively high bit error rate), but one or more other scans (e.g., one or more second scans, one or more third scans, or a combination thereof) corresponding to other word lines 215, other planes 210, or a combination thereof indicate that another error condition does not satisfy one or more thresholds (e.g., e.g., due to a relatively low bit error rate), a memory system 110 may interpret that errors are relatively localized (e.g., to a subset of physical locations of a block 205, to the target word line 215 and one or more adjacent word lines 215). Accordingly, the memory system 110 may trigger a relocation operation to relocate data stored at the target word line 215 and the one or more adjacent word lines 215 (e.g., as a subset of less than all data stored at the block 205). In some examples, such data may be relocated to a different block 205 (e.g., of a same memory device 130, of a different memory device 130). In some examples, such data may be relocated based on (e.g., in response to) none of the word lines 215 for the other scans (e.g., a second scan and a third scan) having a bit error rate that satisfies (e.g., exceeds) a threshold value.

In some examples, a quantity of word lines 215 adjacent to a target word line 215 for data relocation may be configurable. For example, a memory system 110 may modify a quantity of adjacent word lines 215 to be relocated by updating one or more parameters. As such, the memory system 110 may select a size for the subset of the block 205 that may be relocated. Additionally, or alternatively, a host system 105 may configure a quantity of adjacent word lines 215 at a memory system 110.

Accordingly, for circumstances in which a relocation operation involves relocating less data (e.g., three or five word lines, rather than all word lines of a block 205), the relocation operation will be performed faster and consume less power, and the relocation operation will involve less write operations, leading to improved longevity. In some examples, the block may be added to a priority list for error scans (e.g., media scans, background scans, periodic scans), which may check for correctable errors at the block.

In some cases, if other scans (e.g., the second scan and the third scan) on a block 205 also fail, then a relocation operation may involve relocating all data (e.g., all valid data) of the block 205 to another block 205. For example, as the other scans may correspond to (e.g., scan) word lines 215 other than a target word line 215 and the one or more adjacent word lines 215, bit errors detected during these scans may indicate that disturbances may be impacting neighboring planes 210, cold data, weak word lines, or the entire block 205. As such, in some circumstances, all data stored at block 205 may be relocated and errors (e.g., correctable errors) may be corrected. In some other circumstances, if all scans on a block 205 succeed, then a memory system 110 may refrain from performing a relocation operation.

In accordance with these and other techniques, a memory system 110 may thus be configured to determine a quantity of word lines 215 (e.g., a quantity of pages 175-a) for relocating data as part of disturbance error handling, which may implement relocation operations on fewer than all of the word lines 215 of a block 205. Accordingly, performance of a memory system 110 may be improved by reducing latency, power consumption, and write amplification associated with handling disturbance errors.

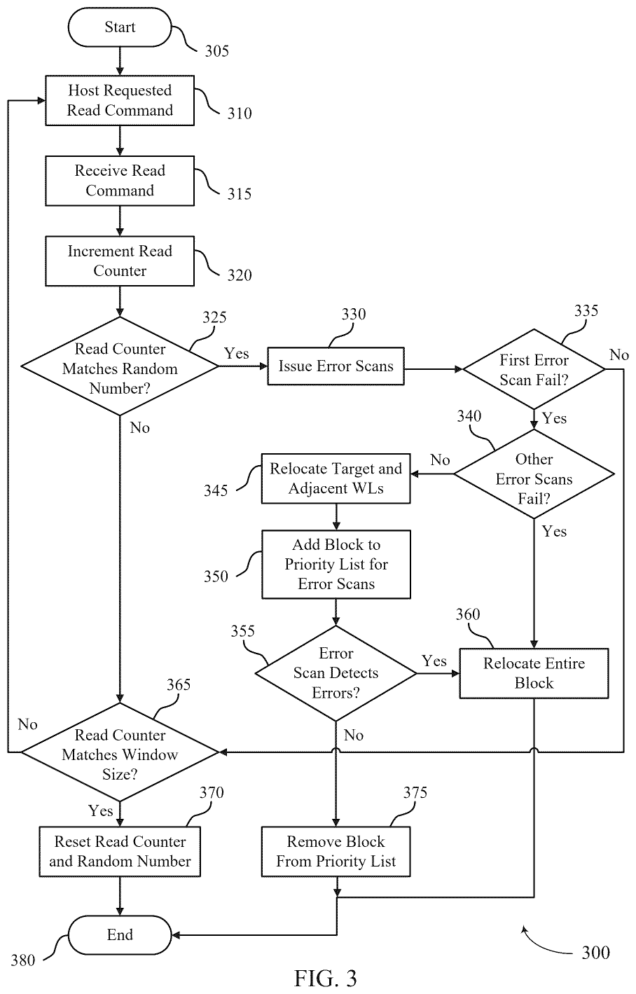

FIG. 3 shows an example of a flowchart 300 that supports disturbance error handling for a memory system in accordance with examples as disclosed herein. Operations of the flowchart 300 may be implemented by a memory system 110 (e.g., a memory system controller 115, one or more local controllers 135, or a combination thereof). The flowchart 300 is depicted to start at 305 and end at 380, but may include additional operations (not shown), or operations may be omitted, modified, or performed in a different order in accordance with the described techniques.

At 310, a host system 105 may issue a read command corresponding to data stored at the memory system 110 (e.g., at a block 205). At 315, the memory system 110 may receive the read command and, at 320, the memory system 110 may increment a read counter (e.g., in response to receiving the read command at 315).

At 325, the memory system 110 may compare the value of the read counter with a random number associated with disturbance error handling. For example, the memory system 110 may have previously generated a random number (e.g., a uniform random number), which may be based on (e.g., have an upper limit based on) a window size associated with disturbance error handling (e.g., a window size corresponding to a size of a block 205). As such, a disturbance error handling procedure may be configured to occur once during each window size. In some examples, the window size may be varied depending on an age of the memory system 110, a total quantity of access operations performed by the memory system, or both. For example, the window size may begin at a first value (e.g., 20,000), and the value may be reduced as a memory system 110 ages. Since a memory system 110 may be more prone to errors as it ages, reducing a value for the window size may increase a frequency for performing a set of scans associated with disturbance error handling. Additionally, or alternatively, a set of error scans may be performed after a quantity of read commands since a prior error scan satisfies a threshold.

If the read counter matches the random number, or the memory system 110 otherwise determines to perform a disturbance error handling procedure, at 330, the memory system 110 may issue a set of error scans. For example, the memory system 110 may issue a first error scan (e.g., an RBER1 scan) to scan a target word line 215, one or more second error scans (e.g., an RBER2 scan) to scan one or more word lines 215 adjacent to the target word line 215, and one or more third error scans (e.g., an RBER3 scan) to scan one or more word lines 215 configured for scanning independently from a target word line 215. A memory system 110 may issue any quantity of errors scans (e.g., first error scans, second error scans, the third errors scans, among other error scans or combinations thereof), and a quantity or one or more such scans may be based on firmware (e.g., a firmware configuration) of the memory system 110 (e.g., of a memory system controller 115), or other characteristics of the memory system 110 (e.g., workloads associated with the memory system 110, types of errors observed or associated with the memory system 110, characteristics of a memory device 130, such as characteristics of a die 160 or characteristics of a block 205).

At 335, the memory system 110 may evaluate whether the first scan failed. For example, the memory system 110 may determine whether a first bit error rate associated with the first scan satisfies (e.g., exceeds) a first threshold. If the first scan fails, at 340, the memory system 110 may evaluate whether the one or more other scans (e.g., RBER2, RBER3, or both) failed. For example, the memory system 110 may determine whether one or more second bit error rates associated with one or more other scans satisfies (e.g., exceeds) a second threshold.

If the other scans succeed (e.g., if a second bit error rate is below the second threshold), at 345, the memory system 110 may relocate data of the target word line 215 and, in some examples, one or more adjacent word lines 215. In some examples, the one or more adjacent word lines may include two word lines 215 immediately adjacent to the target word line (e.g., on opposite sides of a target word line 215). In some cases, the one or more adjacent word lines 215 may also include one or more additional word lines 215 that may be adjacent to the immediately adjacent word lines 215.

At 350, the memory system 110 may add the block 205 to a priority list for error scans. For example, the memory system 110 may update the priority list for the error scans to include an indication of the block 205. As such, during a next error scan (e.g., a media scan, a background scan, a periodic scan), the entire block 205 may be scanned for errors (e.g., correctable error code scan). If, at 355, the error scan on the block 205 performed by the memory system 110 detects an error condition (e.g., that satisfies a threshold level of errors), at 360, all data stored at the block 205 may be relocated to a different block 205 (e.g., of a same memory device 130, or a different memory device 130). Alternatively, if, at 355, the error scan on the block 205 does not detect an error condition, at 375, the block 205 may be removed from the priority list. For example, the priority list may be updated so as to no longer include an indication of the block 205.

If the other error scans fail (e.g., if a detected quantity of bit errors of other word lines 215 or planes 210 exceeds a second threshold), at 360, all data stored at the block 205 may be relocated. In some other circumstances, if, at 325, the read counter does not match the random number, or if, at 335, the first error scan does not fail, the memory system 110 may continue without relocating any portion of the block 205. For example, at 365, the memory system 110 may evaluate whether the current read counter matches the window size. If the read counter does match the window size, at 370, the memory system 110 may reset the read counter and generate a new random number (e.g., a new uniform random number). If the read counter does not match the window size, the memory system 110 may continue processing read commands received from the host at 310. At 380, the process may end for a current window (e.g., as defined by the window size), and may start again at 305 for another window.

Thus, in accordance with one more of the described techniques, a memory system 110 may be configured to determine whether to relocate data of a subset of word lines 215 of a block 205 or all word lines 215 of the block 205 based on bit error rates for multiple error scans (e.g., of different locations of a block 205), thereby supporting relocation operations to be performed, at least in some circumstances, for fewer than all word lines 215 of the block 205. Implementing such techniques may support memory systems 110 having relatively lower power consumption, relatively lower latency, and longer operational life (e.g., due to reduced write amplification), among other benefits.

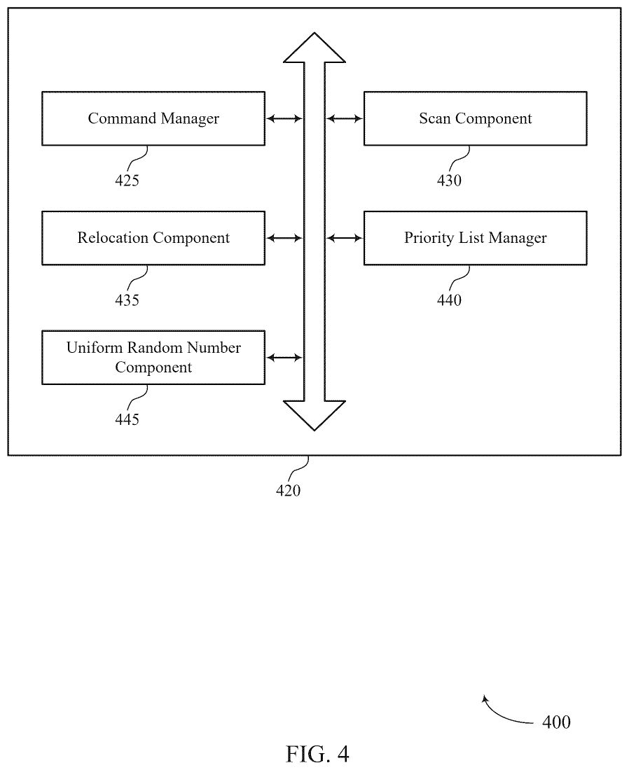

FIG. 4 shows a block diagram 400 of a memory system 420 that supports disturbance error handling for a memory system in accordance with examples as disclosed herein. The memory system 420 may be an example of aspects of a memory system as described with reference to FIGS. 1 through 3. The memory system 420, or various components thereof, may be an example of means for performing various aspects of disturbance error handling for a memory system as described herein. For example, the memory system 420 may include a command manager 425, a scan component 430, a relocation component 435, a priority list manager 440, a uniform random number component 445, or any combination thereof. Each of these components, or components of subcomponents thereof (e.g., one or more processors, one or more memories), may communicate, directly or indirectly, with one another (e.g., via one or more buses).

The command manager 425 may be configured as or otherwise support a means for receiving a read command associated with a first word line of a plurality of word lines of a first block of memory cells of the memory system. The scan component 430 may be configured as or otherwise support a means for performing an error scan, in response to receiving the read command, to determine a respective bit error rate for the first word line and one or more second word lines of the plurality of word lines. The relocation component 435 may be configured as or otherwise support a means for performing a relocation operation in response to the respective bit error rate for the first word line satisfying a first threshold, the relocation operation including relocating, to a second block of memory cells of the memory system, data from a quantity of the plurality of word lines that is in accordance with (e.g., determined as a function of) whether the respective bit error rate for at least one of the one or more second word lines satisfies a second threshold.

In some examples, performing the relocation operation includes relocating data from a subset of the plurality of word lines in response to none of the respective bit error rates for the one or more second word lines satisfying the second threshold. In some examples, the subset of the plurality of word lines corresponds to the first word line and one or more of the plurality of word lines that are physically adjacent to the first word line.

In some examples, the priority list manager 440 may be configured as or otherwise support a means for updating, in response to none of the respective bit error rates for the one or more second word lines satisfying the second threshold, a priority list for performing error scans to include an indication of the first block.

In some examples, performing the relocation operation includes relocating data from all of the plurality of word lines to the second block in response to the respective bit error rate for at least one of the one or more second word lines satisfying the second threshold.

In some examples, the one or more second word lines include one or more word lines that are physically adjacent to the first word line, one or more word lines indicated by a configuration of the memory system, or a combination thereof. In some examples, performing the error scan is in response to a quantity of read commands, including the read command, since a prior error scan satisfying a third threshold.

In some examples, the uniform random number component 445 may be configured as or otherwise support a means for generating a random number, where the third threshold is based at least in part on (e.g., determined as a function of) the random number. In some examples, the third threshold is based at least in part on (e.g., determined as function of) an age of the memory system, a total quantity of operations performed by the memory system, or both. In some examples, the first word line and the one or more second word lines are fewer than all of the plurality of word lines. In some examples, each of the plurality of word lines is associated with a plurality of planes of memory cells of the first block.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

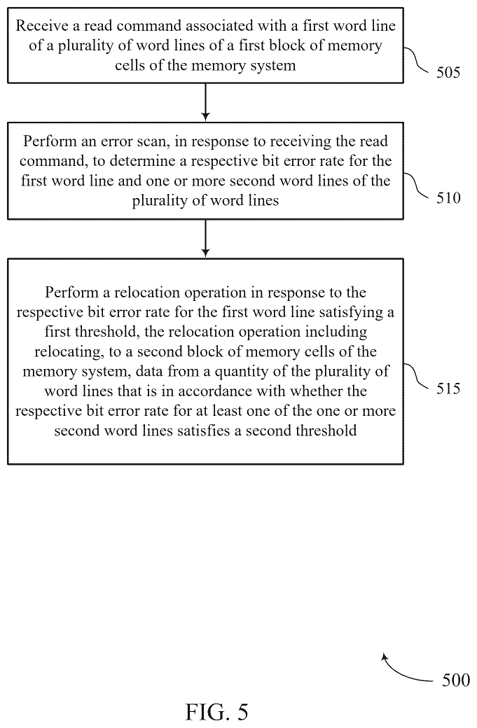

FIG. 5 shows a flowchart illustrating a method 500 that supports disturbance error handling for a memory system in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include receiving a read command associated with a first word line of a plurality of word lines of a first block of memory cells of the memory system. In some examples, aspects of the operations of 505 may be performed by a command manager 425 as described with reference to FIG. 4.

At 510, the method may include performing an error scan, in response to receiving the read command, to determine a respective bit error rate for the first word line and one or more second word lines of the plurality of word lines. In some examples, aspects of the operations of 510 may be performed by a scan component 430 as described with reference to FIG. 4.

At 515, the method may include performing a relocation operation in response to the respective bit error rate for the first word line satisfying a first threshold, the relocation operation including relocating, to a second block of memory cells of the memory system, data from a quantity of the plurality of word lines that is in accordance with (e.g., determined as a function of) whether the respective bit error rate for at least one of the one or more second word lines satisfies a second threshold. In some examples, aspects of the operations of 515 may be performed by a relocation component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a read command associated with a first word line of a plurality of word lines of a first block of memory cells of the memory system; performing an error scan, in response to receiving the read command, to determine a respective bit error rate for the first word line and one or more second word lines of the plurality of word lines; and performing a relocation operation in response to the respective bit error rate for the first word line satisfying a first threshold, the relocation operation including relocating, to a second block of memory cells of the memory system, data from a quantity of the plurality of word lines that is in accordance with whether the respective bit error rate for at least one of the one or more second word lines satisfies a second threshold.

Aspect 2: The method, apparatus, or non-transitory computer-readable medium of aspect 1, where performing the relocation operation includes relocating data from a subset of the plurality of word lines in response to none of the respective bit error rates for the one or more second word lines satisfying the second threshold.

Aspect 3: The method, apparatus, or non-transitory computer-readable medium of aspect 2, where the subset of the plurality of word lines corresponds to the first word line and one or more of the plurality of word lines that are physically adjacent to the first word line.

Aspect 4: The method, apparatus, or non-transitory computer-readable medium of any of aspects 2 through 3, further including operations, features, circuitry, logic, means, or instructions, or any combination thereof for updating, in response to none of the respective bit error rates for the one or more second word lines satisfying the second threshold, a priority list for performing error scans to include an indication of the first block.

Aspect 5: The method, apparatus, or non-transitory computer-readable medium of aspect 1, where performing the relocation operation includes relocating data from all of the plurality of word lines to the second block in response to the respective bit error rate for at least one of the one or more second word lines satisfying the second threshold.

Aspect 6: The method, apparatus, or non-transitory computer-readable medium of any of aspects 1 through 5, where the one or more second word lines include one or more word lines that are physically adjacent to the first word line, one or more word lines indicated by a configuration of the memory system, or a combination thereof.

Aspect 7: The method, apparatus, or non-transitory computer-readable medium of any of aspects 1 through 6, where performing the error scan is in response to a quantity of read commands, including the read command, since a prior error scan satisfying a third threshold.

Aspect 8: The method, apparatus, or non-transitory computer-readable medium of aspect 7, further including operations, features, circuitry, logic, means, or instructions, or any combination thereof for generating a random number, where the third threshold is based at least in part on the random number.

Aspect 9: The method, apparatus, or non-transitory computer-readable medium of any of aspects 7 through 8, where the third threshold is based at least in part on an age of the memory system, a total quantity of operations performed by the memory system, or both.

Aspect 10: The method, apparatus, or non-transitory computer-readable medium of any of aspects 1 through 9, where the first word line and the one or more second word lines are fewer than all of the plurality of word lines.

Aspect 11: The method, apparatus, or non-transitory computer-readable medium of any of aspects 1 through 10, where each of the plurality of word lines is associated with a plurality of planes of memory cells of the first block.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action). Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
receive a read command associated with a first word line of a plurality of word lines of a first block of memory cells of the one or more memory devices;
perform an error scan, in response to receiving the read command, to determine a respective bit error rate for the first word line and one or more second word lines of the plurality of word lines; and
perform a relocation operation in response to the respective bit error rate for the first word line satisfying a first threshold, the relocation operation comprising relocating, to a second block of memory cells of the one or more memory devices, data from a quantity of the plurality of word lines that is in accordance with whether the respective bit error rate for at least one of the one or more second word lines satisfies a second threshold.

2. The memory system of claim 1, wherein, to perform the relocation operation, the processing circuitry is configured to cause the memory system to:
relocate data from a subset of the plurality of word lines in response to none of the respective bit error rates for the one or more second word lines satisfying the second threshold.

3. The memory system of claim 2, wherein the subset of the plurality of word lines corresponds to the first word line and one or more of the plurality of word lines that are physically adjacent to the first word line.

4. The memory system of claim 2, wherein the processing circuitry is further configured to cause the memory system to:
update, in response to none of the respective bit error rates for the one or more second word lines satisfying the second threshold, a priority list for performing error scans to include an indication of the first block.

5. The memory system of claim 1, wherein, to perform the relocation operation, the processing circuitry is configured to cause the memory system to:
relocate data from all of the plurality of word lines to the second block in response to the respective bit error rate for at least one of the one or more second word lines satisfying the second threshold.

6. The memory system of claim 1, wherein the one or more second word lines comprise one or more word lines that are physically adjacent to the first word line, one or more word lines indicated by a configuration of the memory system, or a combination thereof.

7. The memory system of claim 1, wherein the processing circuitry is further configured to cause the memory system to:
perform the error scan in response to a quantity of read commands, including the read command, since a prior error scan satisfying a third threshold.

8. The memory system of claim 7, wherein the processing circuitry is further configured to cause the memory system to:
generate a random number, wherein the third threshold is based at least in part on the random number.

9. The memory system of claim 7, wherein the third threshold is based at least in part on an age of the memory system, a total quantity of operations performed by the memory system, or both.

10. The memory system of claim 1, wherein the first word line and the one or more second word lines are fewer than all of the plurality of word lines.

11. The memory system of claim 1, wherein each of the plurality of word lines is associated with a plurality of planes of memory cells of the first block.

12. A non-transitory computer-readable medium storing code comprising instructions which, when executed by one or more processors of a memory system, cause the memory system to:
receive a read command associated with a first word line of a plurality of word lines of a first block of memory cells of the memory system;
perform an error scan, in response to receiving the read command, to determine a respective bit error rate for the first word line and one or more second word lines of the plurality of word lines; and
perform a relocation operation in response to the respective bit error rate for the first word line satisfying a first threshold, the relocation operation comprising relocating, to a second block of memory cells of the memory system, data from a quantity of the plurality of word lines that is in accordance with whether the respective bit error rate for at least one of the one or more second word lines satisfies a second threshold.

13. The non-transitory computer-readable medium of claim 12, wherein the instructions to perform the relocation operation, when executed by the one or more processors of the memory system, cause the memory system to:
relocate data from a subset of the plurality of word lines in response to none of the respective bit error rates for the one or more second word lines satisfying the second threshold.

14. The non-transitory computer-readable medium of claim 13, wherein the subset of the plurality of word lines corresponds to the first word line and one or more of the plurality of word lines that are physically adjacent to the first word line.

15. The non-transitory computer-readable medium of claim 13, wherein the instructions, when executed by the one or more processors of the memory system, further cause the memory system to:
update, in response to none of the respective bit error rates for the one or more second word lines satisfying the second threshold, a priority list for performing error scans to include an indication of the first block.

16. The non-transitory computer-readable medium of claim 12, wherein the instructions to perform the relocation operation, when executed by the one or more processors of the memory system, cause the memory system to:
relocate data from all of the plurality of word lines to the second block in response to the respective bit error rate for at least one of the one or more second word lines satisfying the second threshold.

17. The non-transitory computer-readable medium of claim 12, wherein the one or more second word lines comprise one or more word lines that are physically adjacent to the first word line, one or more word lines indicated by a configuration of the memory system, or a combination thereof.

18. The non-transitory computer-readable medium of claim 12, wherein the instructions, when executed by the one or more processors of the memory system, cause the memory system to:
perform the error scan in response to a quantity of read commands, including the read command, since a prior error scan satisfying a third threshold.

19. The non-transitory computer-readable medium of claim 18, wherein the instructions, when executed by the one or more processors of the memory system, further cause the memory system to:
generate a random number, wherein the third threshold is based at least in part on the random number.

20. A method at a memory system, comprising:
receiving a read command associated with a first word line of a plurality of word lines of a first block of memory cells of the memory system;
performing an error scan, in response to receiving the read command, to determine a respective bit error rate for the first word line and one or more second word lines of the plurality of word lines; and
performing a relocation operation in response to the respective bit error rate for the first word line satisfying a first threshold, the relocation operation comprising relocating, to a second block of memory cells of the memory system, data from a quantity of the plurality of word lines that is in accordance with whether the respective bit error rate for at least one of the one or more second word lines satisfies a second threshold.

21. The method of claim 20, wherein performing the relocation operation comprises:
relocating data from a subset of the plurality of word lines in accordance with none of the respective bit error rates for the one or more second word lines satisfying the second threshold.

22. The method of claim 21, wherein the subset of the plurality of word lines corresponds to the first word line and one or more of the plurality of word lines that are physically adjacent to the first word line.
